(19) United States
(12) Patent Application Publication
(10) Pub. No.: US 2025/0351589 A1
(43) Pub. Date: Nov. 13, 2025

(54) SILICON-BASED INFRARED BAND AVALANCHE PHOTODETECTOR AND FABRICATION METHOD THEREFOR

(71) Applicant: SOOCHOW UNIVERSITY, Wujiang (CN)

(72) Inventors: Cheng ZHANG, Wujiang (CN); Xiaofeng Li, Wujiang (CN); Binglin Huang, Wujiang (CN); Chenghan Wu, Wujiang (CN); Shaojun Wang, Wujiang (CN); Zefeng Chen, Wujiang (CN)

(21) Appl. No.: 19/278,218

(22) Filed: Jul. 23, 2025

Related U.S. Application Data
(63) Continuation of application No. PCT/CN2024/090322, filed on Apr. 28, 2024.

(30) Foreign Application Priority Data
Mar. 27, 2024 (CN) 202410358352.8

(51) Int. Cl. H10F 30/225; H10F 30/227; H10F 71/00

(52) U.S. Cl. CPC H10F 30/225; H10F 30/227; H10F 71/121

(57) ABSTRACT

The present disclosure provides a silicon-based infrared band avalanche photodetector and a fabrication method thereof. The photodetector includes a bottom electrode layer, a silicon film layer, and a top metal film layer stacked sequentially, where the bottom electrode layer forms an ohmic contact with the silicon film layer, and the top metal film layer forms a Schottky contact with the silicon film layer. The photodetector absorbs near-infrared light through the top metal film layer, generates hot carriers, and injects the hot carriers into the silicon film layer, and the hot carriers are collected by the bottom electrode layer to form a photocurrent, thereby achieving the detection of infrared light with energy below a band gap of silicon. Moreover, broadband or narrowband optical high absorption at different infrared wavelengths can be achieved by adjusting a thickness of the silicon film layer and a type of the top metal film layer.

This application is a Continuation application of PCT/CN2024/090322, filed on Apr. 28, 2024, which claims priority to Chinese Patent Application No. 202410358352.8, filed on Mar. 27, 2024, which is incorporated by reference for all purposes as if fully set forth herein.

### FIELD OF THE INVENTION

The present disclosure relates to the field of photoelectric detection technologies, and in particular, to a silicon-based infrared band avalanche photodetector and a fabrication method therefor.

### DESCRIPTION OF THE RELATED ART

A silicon-based photodetector has advantages such as a mature complementary metal oxide semiconductor (CMOS) manufacturing process, operation at room temperature, and low production costs, and thus is widely applied to fields such as communication, sensing, industrial detection, and medical treatment. With the miniaturization and integration of optoelectronic devices, the development of silicon-based photodetectors for infrared wavelengths that are integrated on a single chip based on mature CMOS technology is an important step in the advancement of silicon photonics technology. While silicon-based photodetectors have found widespread application in the visible spectral range (0.4-0.7 μm), they are not suitable for detecting near-infrared light with a wavelength greater than 1.1 μm because these near-infrared photon energies are insufficient to overcome the silicon band gap (1.12 eV) and induce the photogeneration of electron-hole pairs, that is, no photocurrent is generated. To address the problem that silicon does not absorb infrared light, one solution presented by the silicon photonics industry is to combine low-band gap germanium (0.67 eV) with silicon, or integrate group III-V, II-VI, and VI-VI compound semiconductors on a silicon wafer using wafer bonding technology. Therefore, most of the commercial infrared photodetectors are made of materials based on germanium, indium antimonide, indium gallium arsenide, and mercury cadmium telluride. Although light detection in the infrared band can be achieved, the devices require complex fabrication processes. Moreover, the group III-V, II-VI, and VI-VI materials used are not compatible with the silicon-based CMOS digital readout circuit, and the stability of the materials and the devices is poor.

In order to overcome the above problems, the hot electron photodetection technology is adopted. A metal material is used to absorb light to generate hot carriers, and then the hot carriers are injected into a semiconductor to generate a photocurrent. Since a Schottky energy barrier is lower than the energy band width of the semiconductor, the hot electron detection technology can be used to expand the photodetection band. Such hot electron devices have advantages such as self-driving at room temperature, compatibility with a silicon-based process, and adjustable operating wavelength, detection bandwidth, and polarization sensitivity. However, due to various energy losses in hot electron photodetection, the device efficiency is always below 1% and difficult to reach the commercial level, thereby limiting the practical application of the hot electron devices. Therefore, how to effectively enhance the responsivity of the photodetector while expanding the photodetection band is critical to promoting the commercialization of the hot electron photodetector.

At present, to enhance the responsivity of the hot electron photodetectors, Cheng Zhang et al. designed a gold-coated silicon nanocone structure [Adv. Funct. Mater. 2023, 2304368], which offers tremendous field enhancement and broadband response in a hybrid plasmonic mode along the tapered tip. Ilya Goykhman et al. reported an on-chip integrated metal graphene-silicon plasmonic Schottky photodetector [Nano Lett. 2016, 16, 3005-3013] with avalanche multiplication at a reverse bias of 3 V and a responsivity of 0.37 A/W. Although the responsivity of the photodetectors is improved to a certain extent, the unique nanostructures have high processing requirements and are not suitable for practical production. In addition, the detection band is limited, and the infrared band can be hardly detected.

Based on this, there is an urgent need for a silicon-based infrared photodetector that is of a simple structure, can detect near-infrared light with a wavelength greater than 1.1 μm, has performance comparable to that of commercial germanium and indium gallium arsenide infrared photodetectors, and operates at room temperature.

### SUMMARY OF THE INVENTION

To solve the above technical problems, the present disclosure provides a silicon-based infrared band avalanche photodetector and a fabrication method therefor. The photodetector is of a simple structure, is composed of a bottom electrode layer, a silicon film layer, and a top metal film layer, can detect near-infrared light in a band of 1200-2000 nm, and can excite a strong electric field in a silicon thin film to induce a photoconductive gain and an avalanche effect under application of a small bias voltage, such that the responsivity of the device is comparable to that of commercial germanium and indium gallium arsenide infrared photodetectors. In addition, by selecting the material of the top metal film layer, the photodetector can form a planar Fabry-Perot cavity structure to achieve narrowband light detection, and can excite a strong electric field in a silicon thin film to induce a photoconductive gain and an avalanche effect under application of a small bias voltage, such that the photoresponsivity of the device is enhanced by three to four orders of magnitude; the narrowband peak wavelength can be adjusted by controlling the thickness of the silicon film layer.

The present disclosure provides the following technical solutions:

A first aspect of the present disclosure provides a silicon-based infrared band avalanche photodetector, including a bottom electrode layer, a silicon film layer, and a top metal film layer stacked sequentially;
the top metal film layer forms a Schottky contact with the silicon film layer; and
the thickness of the silicon film layer is 10 nm-5 μm.

The silicon-based infrared band avalanche photodetector provided in the present disclosure is composed of only a bottom electrode layer, a silicon film layer, and a top metal film layer. Near-infrared light is absorbed by the top metal film layer, a transition metal layer forms a Schottky junction with silicon, and photoexcited hot carriers generated in the top metal film layer under illumination overcome a Schottky barrier and are injected into the silicon film layer, and then collected by the bottom electrode layer to form a photocurrent, thereby achieving the detection of infrared light with energy below the band gap of silicon.

Further, the bottom electrode layer forms an Ohmic contact with the silicon film layer, which is conducive to collecting photo-generated carriers; meanwhile, the bottom electrode layer, as an optical reflector, can improve the light absorption efficiency of the top metal film layer.

Further, the material of the bottom electrode layer is selected from the group consisting of aluminum, a noble metal and a transition metal, preferably selected from the group consisting of titanium, gold, silver, copper, chromium and aluminum.

Further, the thickness of the bottom electrode layer is preferably greater than 30 nm, for example, 50-200 nm.

Further, the bottom electrode layer is obtained by sequentially stacking a titanium film layer, a gold film layer, and an aluminum film layer, and the aluminum film layer is attached to the silicon film layer. More preferably, the thickness of the titanium film layer is greater than 2 nm, the thickness of the gold film layer is greater than 40 nm, and the thickness of the aluminum film layer is greater than 30 nm. The bottom electrode layer is obtained by stacking the above three metal films, and the aluminum film layer is attached to the silicon film layer, such that the contact barrier between the bottom electrode layer and the silicon film layer is reduced, while the stacked titanium film layer and gold film layer can improve the light reflection of the bottom electrode layer, thereby improving the light absorption efficiency of the top metal film layer.

Further, the material of the silicon film layer is a lightly doped n-type crystalline silicon material or a lightly doped p-type crystalline silicon material. In a case that the silicon film layer is a lightly doped n-type or p-type silicon film, the silicon film layer forms an ohmic contact with the aluminum film layer. More preferably, the resistivity of the silicon film layer is preferably 0.1-100 Ω·cm.

Further, the thickness of the silicon film layer may be any value of 10-100 nm, 100-200 nm, 200-300 nm, 300-400 nm, 400-500 nm, 500 nm-1 μm, 1-2 μm, 2-3 μm, 3-4 μm, and 4-5 μm, more preferably 10 nm-1 μm. The silicon film layer of the silicon-based photodetector claimed in the present disclosure has a thickness much less than the thickness (several hundred micrometers) of the silicon substrate in the existing silicon-based photodetector. More preferably, the thickness of the silicon film layer is less than the width of the depletion layer of the Schottky junction formed by the silicon film layer and the top metal film layer, which facilitates the collection of carriers by the bottom electrode layer.

Further, the material of the top metal film layer is selected from the group consisting of gold, silver, titanium, copper, chromium, aluminum, titanium nitride, and an alloy including at least two of the metal elements (gold, silver, titanium, copper, chromium, aluminum). The top metal film layer is configured to absorb near-infrared light, forms a Schottky contact with the silicon film layer, and enables photoexcited hot carriers generated under illumination to overcome a Schottky barrier and be injected into the silicon film layer. Preferably, the thickness of the top metal film layer is 5-100 nm, such as 10 nm, 20 nm, 30 nm, 40 nm, 50 nm, 60 nm, 70 nm, 80 nm, or 90 nm, including, but not limited to, the thickness values listed above, and may also be other thickness values within the above range. More preferably, the thickness of the top metal film layer is less than an electron mean free path, such that most infrared light can be absorbed.

Further, when a bias voltage of 1-10 V, preferably 5 V or less, is applied to the photodetector, the responsivity of the photodetector in a near-infrared band of 1200-2000 nm may reach 0.1-0.35 A/W (the bias voltage is generally 5 V or less). When a bias voltage is applied, a high-intensity electric field can be formed in the silicon thin film between the upper and lower metal film layers, and carriers obtain energy and accelerate in the electric field, leading to a photoconductive gain and an avalanche multiplication effect, thereby enhancing the photocurrent by three to four orders of magnitude and improving the photoelectric responsivity. However, the magnitude of the bias voltage that the photodetector can withstand is related to the thickness of the silicon thin film; the thicker the silicon thin film, the greater the bias voltage that the photodetector can withstand. When the thickness of the silicon thin film is small, applying a too-large bias voltage may break down the device, such that the device fails to operate. For a photodetector with a silicon film layer thickness of 10 nm-5 μm, the bias voltage applied is preferably 1-10 V, and more preferably 5 V or less.

Further, when the material of the top metal film layer is selected from the group consisting of titanium, chromium, and titanium nitride, for example, titanium, broadband absorption in a near-infrared band of 1200-2000 nm can be achieved, and the responsivity of the photodetector in the near-infrared band of 1200-2000 nm reaches 0.1-0.35 A/W, which is comparable to the performance of a commercial infrared photodetector based on germanium and indium gallium arsenide materials. Further, when the material of the top metal film layer is selected from the group consisting of gold, silver, copper, aluminum, and an alloy including at least two of the metal elements (gold, silver, copper, aluminum), the top metal film layer forms a Fabry-Perot cavity with the bottom electrode layer, the silicon film layer is a dielectric layer in the Fabry-Perot cavity, and narrowband optical absorption at different infrared wavelengths is achieved by adjusting the thickness of the silicon film layer. Preferably, when the top metal film layer is made of gold, an adhesion layer is disposed between the top metal film layer and the silicon film layer, and the material of the adhesion layer is preferably one or more of titanium, chromium, aluminum, and silver, so as to improve adhesion between the top metal film layer and the silicon film layer.

Narrowband silicon-based optoelectronic devices have been widely applied to various fields, since such devices can selectively respond to light of a specific wavelength but do not respond to light of another wavelength. However, at present, narrowband photodetectors are mainly integrated by inorganic semiconductors and optical filters, which leads to complex devices and limits the pixel density of the detector array. Narrowband photodetectors without optical filters, which are constructed by using materials with narrowband absorption, utilizing the plasma effect to enhance absorption in a selected wavelength range, or controlling the internal quantum efficiency by narrowing the charge collection, have problems such as low sensitivity and complex processing technology for the required micro-nano structure.

According to the silicon-based photodetector provided in the present disclosure, the structure is simple, and by selecting the material of the top metal film layer, the top metal film layer may form a Fabry-Perot cavity with the bottom electrode layer, such that the optical absorption efficiency of the top metal film layer can be enhanced by optical resonance without the need for a micro-nano structure, and the absorption peak wavelength can be controlled by adjusting the thickness of the silicon thin film as the dielectric layer, so as to achieve narrowband light absorption in the infrared band. In addition, under the application of a bias voltage, the photodetector can effectively improve the responsivity of the device while maintaining the narrowband characteristics.

A second aspect of the present disclosure provides a fabrication method for the silicon-based infrared band avalanche photodetector according to the first aspect, including the following steps:
placing a pretreated silicon-on-insulator substrate in a hydrofluoric acid solution, and removing an insulating layer to obtain the silicon film layer; and
fabricating the top metal film layer and the bottom electrode layer on the upper surface and the lower surface of the silicon film layer respectively by a physical and/or chemical method.

Further, the pretreatment includes a process of ultrasonic cleaning of the silicon-on-insulator with an organic solvent and water in sequence; the physical and/or chemical method includes magnetron sputtering deposition and electron beam evaporation.

In the present disclosure, the silicon-on-insulator is placed in a hydrofluoric acid solution, and the insulating layer (for example, silicon dioxide) is dissolved by hydrofluoric acid, thereby obtaining an ultra-thin silicon film on the surface of the silicon-on-insulator.

Compared with the prior art, the present disclosure has the following beneficial effects:
1. The present disclosure provides a silicon-based infrared band avalanche photodetector, which is composed of only a bottom electrode layer, an ultra-thin silicon film layer, and a top metal film layer. The silicon-based infrared band avalanche photodetector is of a simple structure, easy to fabricate, suitable for mass production, and lightweight and thin, meeting the requirements for device miniaturization. Meanwhile, by selecting the material of the top metal film layer, broadband absorption or narrowband absorption in the near-infrared band can be achieved, thereby meeting different application requirements.
2. The silicon-based infrared band avalanche photodetector provided in the present disclosure is of a planar multilayer structure and is insensitive to polarization and incident angles. When serving as a broadband absorption device, the photodetector has a relatively large tolerance in the thickness variation of the multilayer thin film structure. When the bottom electrode layer, the ultra-thin silicon film layer, and the top metal film layer form a Fabry-Perot cavity, narrowband light absorption can be achieved in an infrared band, and the center wavelength of the narrowband can be controlled by adjusting the thickness of the silicon thin film, such that the photodetector can serve as a narrowband absorption device.
3. When a bias voltage is applied to both ends of the above photodetector, a strong electric field may be generated in the silicon film layer located between the upper and lower metal film layers, and carriers obtain energy and accelerate in the electric field, leading to a photoconductive gain and an avalanche multiplication effect, thereby enhancing the photocurrent by three to four orders of magnitude and greatly improving the responsivity of the device to the near-infrared light wavelength. When the photodetector serves as a narrowband absorption device, the application of a bias voltage may enhance the responsivity of the device, while the full width at half maximum is substantially unchanged, and the narrowband characteristics can still be maintained. For example, according to the broadband photodetector fabricated in the present disclosure, under a bias voltage of −2 V, the device achieves a photoresponsivity of approximately 0.3 A/W at 1600-1800 nm, representing an increase of more than three orders of magnitude compared to the photoresponsivity under zero bias voltage. In addition, according to the fabricated narrowband photodetector, under a bias voltage of 1.9 V, the device achieves a photoresponsivity of 0.2 A/W at 1550 nm; the narrowband peak absorption wavelength may be adjusted to 1780 nm by controlling the thickness of the silicon film layer of the device, and the responsivity of the device reaches 0.12 A/W under a bias voltage of 3 V, representing an increase of more than three orders of magnitude compared to the photoresponsivity under zero bias voltage, which is comparable to the performance of a commercial infrared photodetector based on germanium and indium gallium arsenide materials.

### BRIEF DESCRIPTION OF THE DRAWINGS

FIG. 1 shows a schematic structural diagram of a silicon-based infrared band avalanche photodetector fabricated in Example 1, where 1 represents a bottom electrode layer, 2 represents a silicon film layer, and 3 represents a top metal film layer.

FIG. 2 shows a flowchart of fabricating a silicon-based infrared band avalanche photodetector according to Example 1.

In FIG. 3: FIG. 3a shows a light absorption/reflection spectrum of the silicon-based infrared band avalanche photodetector fabricated in Example 1, where a solid line represents an absorptance curve, and a dashed line represents a reflectance curve; FIG. 3b shows a dark current-voltage curve of the photodetector.

In FIG. 4: FIG. 4a shows a photocurrent-time curve of the silicon-based infrared band avalanche photodetector fabricated in Example 1 when irradiated by lasers of different wavelengths under zero bias voltage; FIG. 4b shows a responsivity curve of the silicon-based infrared band avalanche photodetector fabricated in Example 1 under zero bias voltage in a band of 1200 nm-2000 nm.

FIG. 5 shows photocurrent-time curves of the silicon-based infrared band avalanche photodetector fabricated in Example 1 at different wavelengths under different bias voltages, where FIG. 5a shows a bias voltage of −1 V, and FIG. 5b shows a bias voltage of −2 V.

In FIG. 6: FIG. 6a shows a responsivity curve of the silicon-based infrared band avalanche photodetector fabricated in Example 1 under different bias voltages (−0.5 V, −1 V, −1.5 V, and −2 V);

FIG. 6b shows a photocurrent gain curve of the silicon-based infrared band avalanche photodetector fabricated in Example 1 under different bias voltages, with a wavelength of 1600 nm as an example.

FIG. 7 shows a schematic structural diagram of a silicon-based infrared band avalanche photodetector fabricated in Example 2, where 1 represents a bottom electrode layer, 2 represents a silicon film layer, 3 represents an adhesion layer, and 4 represents a top metal film layer.

FIG. 8 shows a flowchart of fabricating a silicon-based infrared band avalanche photodetector according to Example 2.

FIG. 9 shows a light absorption/reflection spectrum of the silicon-based infrared band avalanche photodetector fabricated in Example 2, where a solid line represents a reflectance curve, and a dashed line represents an absorptance curve.

FIG. 10 shows a dark current-voltage curve of the silicon-based infrared band avalanche photodetector fabricated in Example 2.

FIG. 11 shows a responsivity curve of the silicon-based infrared band avalanche photodetector fabricated in Example 2 at different wavelengths under zero bias voltage.

FIG. 12 shows a responsivity curve of the silicon-based infrared band avalanche photodetector fabricated in Example 2 at different wavelengths under a bias voltage of 1.9 V.

FIG. 13 shows a light absorption/reflection spectrum of the silicon-based infrared band avalanche photodetector fabricated in Example 3, where a solid line represents a reflectance curve, and a dotted line represents an absorptance curve.

FIG. 14 shows a responsivity curve of the silicon-based infrared band avalanche photodetector fabricated in Example 3 at different wavelengths under zero bias voltage.

FIG. 15 shows a responsivity curve of the silicon-based infrared band avalanche photodetector fabricated in Example 3 at different wavelengths under a bias voltage of 3 V.

### DETAILED DESCRIPTION OF THE PREFERRED EMBODIMENTS

Unless defined otherwise, all technical and scientific terms used herein have the same meaning as commonly understood by those skilled in the art to which the present disclosure pertains. The terms used in the specification of the present disclosure are only for the purpose of describing specific examples, and are not intended to limit the present disclosure. The term “and/or” used herein includes any and all combinations of one or a plurality of related listed items. The term “include” or “comprise” described in the present disclosure means that other components may also be included or comprised in addition to the described components. The “include” or “comprise” described in the present disclosure may also be replaced with a closed term “is” or “composed of”.

The present disclosure will be further described below with reference to the examples and drawings, such that those skilled in the art can better understand and implement the present disclosure. However, the examples should not be construed as limiting the present disclosure.

### Example 1

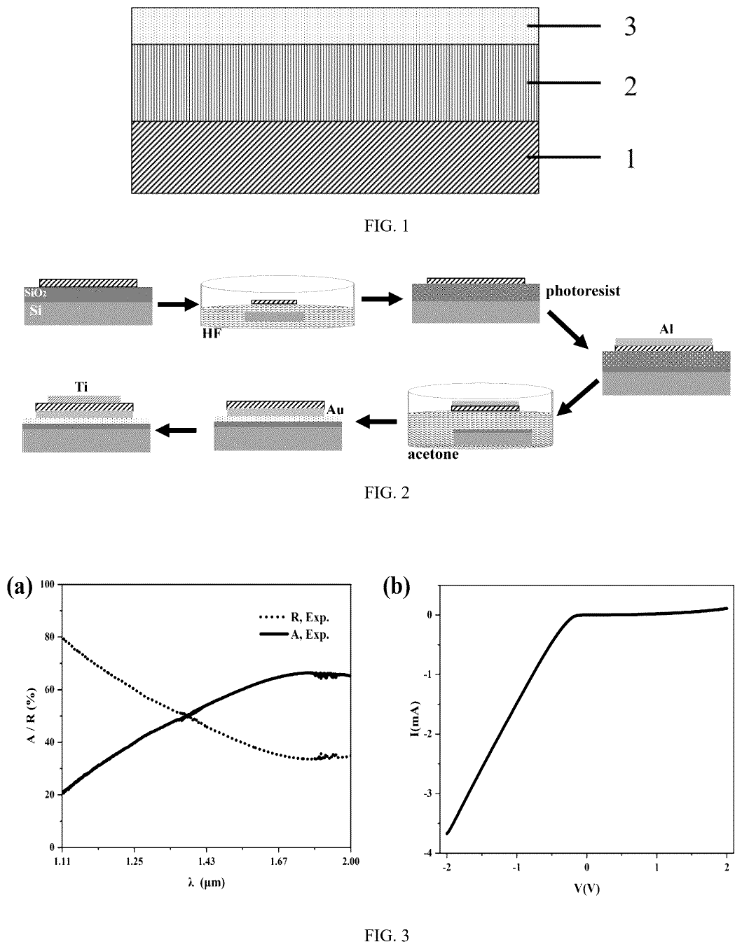

The example relates to the fabrication of a silicon-based infrared band avalanche photodetector with broadband absorption. The structure thereof is shown in FIG. 1, including from bottom to top: a bottom electrode layer 1: a titanium film layer with a thickness of 5 nm, a gold film layer with a thickness of 70 nm, and an aluminum film layer with a thickness of 70 nm stacked sequentially from bottom to top;
a silicon film layer 2: with a thickness of 100 nm; and
a top metal film layer 3: a titanium film layer with a thickness of 20 nm.

A polished silicon oxide wafer with a top layer of silicon oxide 300 nm thick is used as a substrate to carry the photodetector.

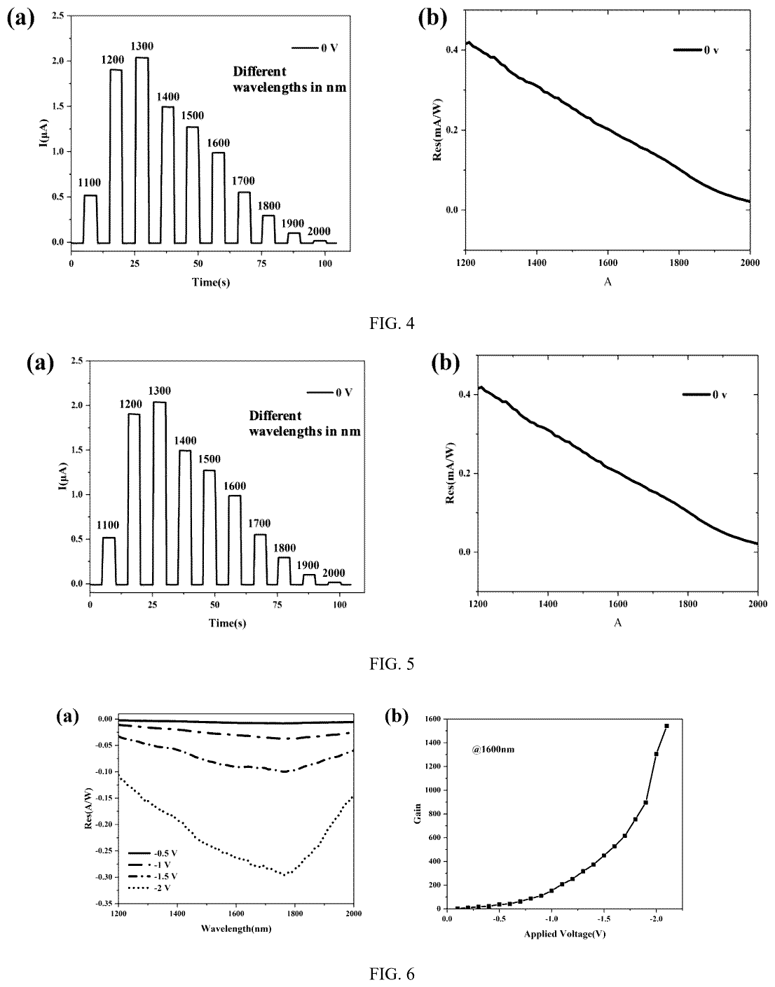

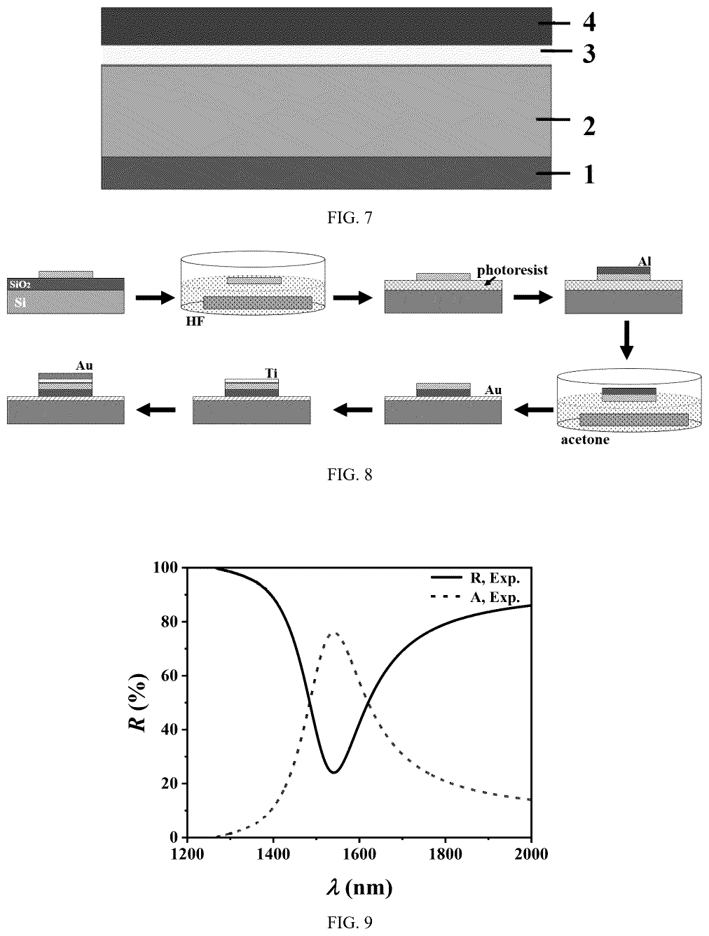

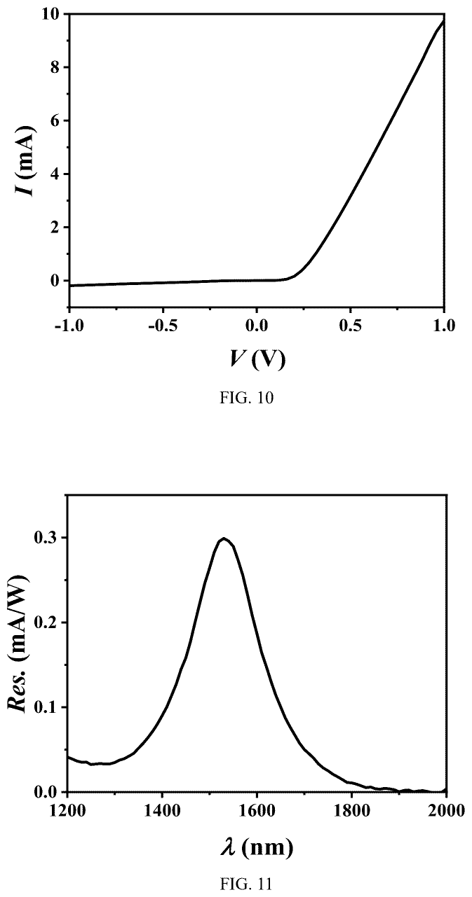

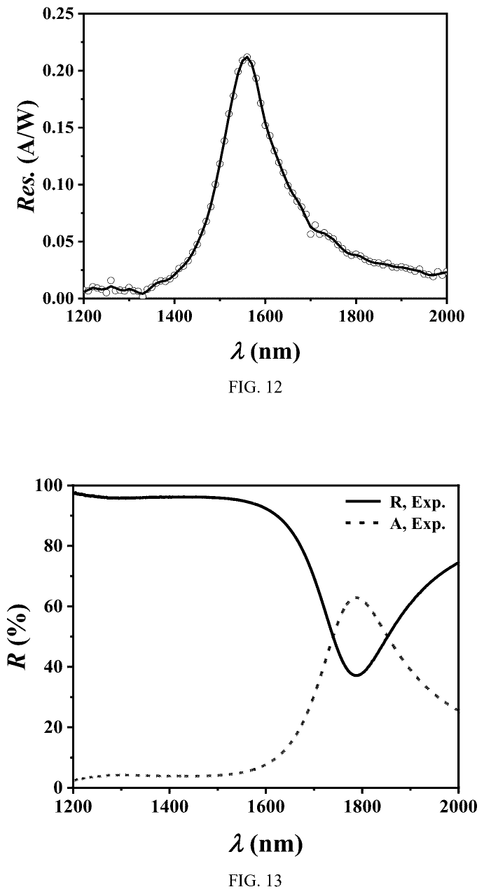

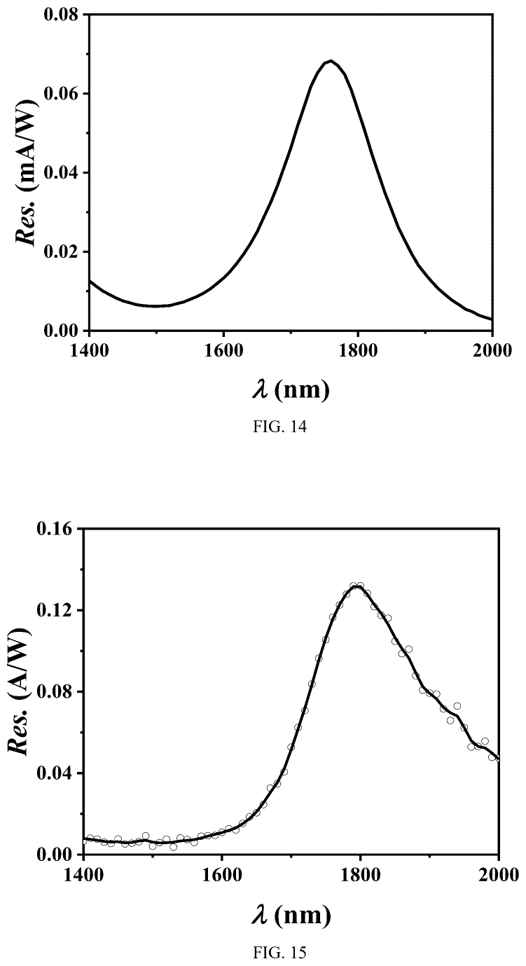

The fabrication process of the photodetector is shown in FIG. 2, and is specifically as follows:
(1) A commercial silicon-on-insulator (SOI) substrate that had been ultrasonically cleaned with acetone, ethanol, and deionized water was placed in a hydrofluoric acid solution with a percentage by volume of 40%. After a silicon oxide layer was removed, a silicon thin film suspended in the solution was obtained.
(2) The ultra-thin silicon film layer fabricated in step (1) was transferred to the surface of a substrate spin-coated with PMMA, and air-dried. Then an aluminum film layer with a thickness of 70 nm was deposited on the surface of the ultra-thin silicon film layer by using a magnetron sputtering technology (pre-sputtering was performed for 5 min before the thin film deposition, the degree of vacuum for deposition was 5×10⁻⁴ Pa, and the parameters of the magnetron sputtering were as follows: the target material was an aluminum target, the power was 50 W, argon was introduced during sputtering, and the pressure in the chamber was 1 Pa).
(3) Then, the composite structure was transferred to acetone and left to stand to obtain a composite thin film 1 suspended in the organic solvent, and the composite thin film was transferred to a titanium gold electrode and air-dried to obtain a composite thin film 2 including a bottom electrode layer and a silicon film layer. The titanium gold electrode was fabricated on the substrate by using an electron beam evaporation method (pre-sputtering was performed for 5 min before the thin film deposition, and the parameters of the electron beam evaporation were as follows: the evaporation material was titanium gold granules, the evaporation rate was 0.5 A/s, the pre-evaporation power was 30%, the evaporation power was 30%, the operation vacuum was 5e⁻⁴ Pa, and the operation temperature was 20° C.).
(4) A layer of photoresist was applied on the silicon film layer of the composite thin film 2, a window smaller than the silicon thin film was exposed by using an ultraviolet exposure system, and then a titanium metal film layer with a thickness of 20 nm was deposited by using an electron beam evaporation technology (pre-sputtering was performed for 5 min before the thin film deposition, and the parameters of the electron beam evaporation were as follows: the evaporation material was titanium gold granules, the evaporation rate was 0.5 A/s, the operation vacuum was 5e⁻⁴ Pa, and the operation temperature was 20° C.). Then, the device was soaked in an acetone solution, left to stand for a period of time, and then taken out and air-dried to fabricate the silicon-based photodetector.

According to the photodetector fabricated by the above fabrication method, the thickness of each metal film layer can be controlled by controlling the parameters in the deposition process, thereby ensuring the uniformity of the thickness of the metal film layer.

### Performance Test:

The optical and electrical performance of the silicon-based photodetector fabricated in this example was tested as follows:
(1) Testing the optical absorptance and reflectance of the photodetector by using a spectrometer The test results are shown in FIG. 3a. The silicon-based photodetector fabricated in this example has an average absorptance of more than 50% in the near-infrared band of 1200-2000 nm. It can be seen that the silicon-based photodetector can achieve broadband absorption in this band.
(2) Testing the electrical response of the photodetector by using a micro-area testing platform FIG. 3b shows a current-voltage curve of the photodetector at a voltage of −2 V to 2 V. It can be seen from the figure that the top metal film forms a Schottky junction with the silicon film, and the silicon film is in ohmic contact with the aluminum film in the bottom electrode layer.
(3) Studying the influence of a bias voltage on the responsivity of the photodetector

FIG. 4a shows a photocurrent curve of the photodetector under zero bias voltage to near-infrared light at different wavelengths as the light is turned on and off over time, with a wavelength range from 1100 nm-2000 nm and an interval of 100 nm. It can be seen from the figure that the photodetector has an electrical photoresponse to near-infrared light of 1100 nm-2000 nm. By measuring the photocurrent of the photodetector with a smaller wavelength interval and the light output power of the corresponding laser, the responsivity curve of the photodetector in the near-infrared band of 1200 nm-2000 nm as shown in FIG. 4b is obtained, further indicating that the photodetector fabricated in this example achieves broadband absorption in the band of 1200 nm-2000 nm.

FIG. 5 shows the photocurrent-time curves of the photodetector when irradiated by lasers of different wavelengths under different bias voltages, with a wavelength range from 1100 nm-2000 nm and an interval of 100 nm. FIG. 5a shows a photocurrent-time curve under a bias voltage of −1 V. It can be seen from the figure that the photocurrent at 1600 nm reaches 150 μA, which represents a 154-fold gain of the photocurrent of 1 μA at 1600 nm under a bias voltage of 0 V. FIG. 5b shows the photocurrent-time curve under a bias voltage of −2 V. It can be seen from the figure that the photocurrent at 1600 nm reaches 1.492 mA, which represents a 1492-fold gain compared to the photocurrent of 1 μA at 1600 nm under a bias voltage of 0 V; the dark current of the sample is relatively stable under high gain.

FIG. 6a is a photoresponsivity curve of the photodetector to light at different wavelengths under different bias voltages. It can be seen from the figure that with the increase of the bias voltage, the photoresponsivity also increases obviously; when the bias voltage is increased to −2 V, the responsivity to the near-infrared light of 1600-1800 nm is close to 0.3 A/W. Moreover, it can be seen from FIG. 6b (the gain of the photocurrent at the wavelength of 1600 nm under different bias voltages relative to the gain under zero bias voltage) that with the increase of the bias voltage, the gain of the photocurrent also increases, and the highest gain multiple can reach three to four orders of magnitude.

### Example 2

The example relates to the fabrication of a silicon-based infrared band avalanche photodetector with narrowband absorption. The structure thereof is shown in FIG. 7, including from bottom to top:
a bottom electrode layer 1: a titanium film layer with a thickness of 5 nm, a gold film layer with a thickness of 70 nm, and an aluminum film layer with a thickness of 70 nm stacked sequentially from bottom to top;
a silicon film layer 2: with a thickness of 100 nm;
an adhesion layer 3: a titanium film layer with a thickness of 5 nm; and
a top metal film layer 4: a gold film layer of 14 nm.

A polished silicon oxide wafer with a top layer of silicon oxide 300 nm thick is used as a substrate to carry the photodetector.

The fabrication process of the photodetector is shown in FIG. 8, and is specifically as follows:
(1) A commercial silicon-on-insulator (SOI) substrate that had been ultrasonically cleaned with acetone, ethanol, and deionized water was placed in a hydrofluoric acid solution with a percentage by volume of 40%. After a silicon oxide layer was removed, a silicon thin film suspended in the solution was obtained.
(2) The ultra-thin silicon film layer fabricated in step (1) was transferred to the surface of a substrate spin-coated with PMMA, and air-dried. Then an aluminum film layer with a thickness of 70 nm was deposited on the surface of the ultra-thin silicon film layer by using a magnetron sputtering technology (pre-sputtering was performed for 5 min before the thin film deposition, the degree of vacuum for deposition was 5×10⁻⁴ Pa, and the parameters of the magnetron sputtering were as follows: the target material was an aluminum target, the power was 50 W, argon was introduced during sputtering, and the pressure in the chamber was 1 Pa).
(3) Then, the composite structure was transferred to acetone and left to stand to obtain a composite thin film 1 suspended in the organic solvent, and the composite thin film was transferred to a titanium gold electrode and air-dried to obtain a composite thin film 2 including a bottom electrode layer and a silicon film layer. The titanium gold electrode was fabricated on the substrate by using an electron beam evaporation method (pre-sputtering was performed for 5 min before the thin film deposition, and the parameters of the electron beam evaporation were as follows: the evaporation material was titanium gold granules, the evaporation rate was 0.5 A/s, the pre-evaporation power was 30%, the evaporation power was 30%, the operation vacuum was 5e⁻⁴ Pa, and the operation temperature was 20° C.).
(4) A layer of photoresist was applied on the silicon film layer of the composite thin film 2, a window smaller than the silicon thin film was exposed by using an ultraviolet exposure system, and then a titanium film layer with a thickness of 5 nm and a gold film layer with a thickness of 14 nm were deposited by using an electron beam evaporation technology (pre-sputtering was performed for 5 min before the thin film deposition, and the parameters of the electron beam evaporation were as follows: the evaporation material was titanium or gold granules, the evaporation rate was 0.5 A/s, the pre-evaporation power was 30%, the evaporation power was 30%, the operation vacuum was 5e⁻⁴ Pa, and the operation temperature was 20° C.). Then, the device was soaked in an acetone solution, left to stand for a period of time, and then taken out and air-dried to fabricate the silicon-based photodetector.

According to the photodetector fabricated by the above fabrication method, the thickness of each metal film layer can be controlled by controlling the parameters in the deposition process, thereby ensuring the uniformity of the thickness of the metal film layer.

### Performance Test:

The optical and electrical performance of the silicon-based photodetector fabricated in this example was tested as follows:
(1) Testing the optical absorptance and reflectance of the photodetector by using a spectrometer

The test results are shown in FIG. 9. The silicon-based photodetector fabricated in this example has a reflectance of only 20% and an absorptance of up to 80% in the near-infrared band of 1550 nm, with a full width at half maximum of the absorption wavelength of 200 nm. It can be seen that the silicon-based photodetector can achieve narrowband absorption in this band.
(2) Testing the electrical response of the photodetector by using a micro-area testing platform

FIG. 10 shows a current-voltage curve of the photodetector at a voltage of −1 V to 1 V. It can be seen from the figure that the top metal film forms a Schottky junction with the silicon film, and the silicon film is in ohmic contact with the aluminum film in the bottom electrode layer.
(3) Studying the influence of a bias voltage on the responsivity of the photodetector

FIG. 11 shows a responsivity curve of the photodetector in the near-infrared band of 1200 nm-2000 nm under zero bias voltage, and a narrowband response curve consistent with the trend of the optical reflection spectrum is obtained, further indicating that the photodetector can achieve narrowband absorption at the wavelength of 1550 nm.

FIG. 12 shows a responsivity curve of the photodetector in the near-infrared band of 1200 nm-2000 nm under a bias voltage of 1.9 V. The wavelength with the highest response is still at 1550 nm, and the full width at half maximum of the narrowband response is still maintained at 200 nm, indicating that the application of the bias voltage does not change the narrowband absorption characteristics of the photodetector. In addition, the responsivity of the photodetector at 1550 nm reaches 0.2 A/W under a bias voltage of 1.9 V, with a gain multiple of three orders of magnitude compared to the responsivity under a bias voltage of 0 V, which is comparable to the performance of a commercial detector based on germanium and indium gallium arsenide materials.

### Example 3

The example relates to a silicon-based infrared band avalanche photodetector with narrowband absorption, which differs from Example 2 only in that: the thickness of the silicon film layer is 190 nm, and the rest is the same.

### Performance Test:

(1) Testing the optical absorptance and reflectance of the photodetector by using a spectrometer

The test results are shown in FIG. 13. The silicon-based photodetector fabricated in this example has a reflectance of 35% and an absorptance of 65% in the near-infrared band of 1780 nm, and with a full width at half maximum of the absorption wavelength of 220 nm, indicating that the silicon-based photodetector fabricated in this example can achieve narrowband absorption in the band of 1780 nm. It can be seen that by adjusting the thickness of the silicon film layer in the photodetector fabricated in Example 2, narrowband absorption in different bands can be achieved.
(2) Studying the influence of a bias voltage on the responsivity of the photodetector

FIG. 14 shows a responsivity curve of the photodetector in the near-infrared band of 1400 nm-2000 nm under zero bias voltage, and a narrowband response curve consistent with the trend of the optical reflection spectrum is obtained, further indicating that the photodetector can achieve narrowband absorption at the wavelength of 1780 nm.

FIG. 15 shows a responsivity curve of the photodetector in the near-infrared band of 1400 nm-2000 nm under a bias voltage of 3 V. The wavelength with the highest response is still at 1780 nm, the responsivity reaches 0.12 A/W, the full width at half maximum of the narrowband response peak is maintained at 220 nm, and the gain multiple reaches three orders of magnitude.

In summary, the silicon-based photodetector provided in the present disclosure can achieve broadband absorption or narrowband absorption of near-infrared light by adjusting the material of the top metal film layer, thereby meeting different application requirements. In addition, the silicon-based photodetector can generate an avalanche multiplication effect under the application of a bias voltage, thereby greatly enhancing the photoresponsivity of the device, and enabling the responsivity of the silicon-based photodetector to be comparable to the performance of a commercial detector based on germanium and indium gallium arsenide materials.

The above-mentioned examples are merely preferred examples for adequately illustrating the present disclosure, rather than limiting the protection scope of the present disclosure. Equivalent substitutions or modifications made by those skilled in the art on the basis of the present disclosure shall all fall within the protection scope of the present disclosure. The protection scope of the present disclosure is subject to the claims.

1. A silicon-based infrared band avalanche photodetector, comprising a bottom electrode layer, a silicon film layer, and a top metal film layer stacked sequentially, wherein
the top metal film layer forms a Schottky contact with the silicon film layer; and
a thickness of the silicon film layer is 10 nm-5 μm.

2. The silicon-based infrared band avalanche photodetector according to claim 1, wherein the bottom electrode layer forms an ohmic contact with the silicon film layer;
and/or, a material of the bottom electrode layer is selected from the group consisting of aluminum, a noble metal and a transition metal, preferably selected from the group consisting of titanium, gold, silver, copper, chromium and aluminum;
and/or, a thickness of the bottom electrode layer is greater than 30 nm.

3. The silicon-based infrared band avalanche photodetector according to claim 2, wherein the bottom electrode layer is obtained by sequentially stacking a titanium film layer, a gold film layer, and an aluminum film layer, and the aluminum film layer is attached to the silicon film layer.

4. The silicon-based infrared band avalanche photodetector according to claim 1, wherein a material of the silicon film layer is a lightly doped n-type crystalline silicon material or a lightly doped p-type crystalline silicon material;
and/or, a resistivity of the silicon film layer is 0.1-100 Ω·cm.

5. The silicon-based infrared band avalanche photodetector according to claim 1, wherein a material of the top metal film layer is selected from the group consisting of gold, silver, titanium, copper, chromium, aluminum, titanium nitride, and an alloy comprising at least two of gold, silver, titanium, copper, chromium and aluminum;
and/or, a thickness of the top metal film layer is 5-100 nm.

6. The silicon-based infrared band avalanche photodetector according to claim 1, wherein the thickness of the top metal film layer is less than an electron mean free path;
and/or, the thickness of the silicon film layer is less than a depletion layer width of a Schottky junction formed by the silicon film layer and the top metal film layer.

7. The silicon-based infrared band avalanche photodetector according to claim 1, wherein when a material of the top metal film layer is selected from the group consisting of gold, silver, copper, aluminum, and an alloy comprising at least two of gold, silver, copper, aluminum, the top metal film layer forms a Fabry-Perot cavity with the bottom electrode layer, the silicon film layer is a dielectric layer in the Fabry-Perot cavity, and narrowband optical absorption at different infrared wavelengths is achieved by adjusting the thickness of the silicon film layer.

8. The silicon-based infrared band avalanche photodetector according to claim 7, wherein when the material of the top metal film layer is gold, an adhesion layer is disposed between the top metal film layer and the silicon film layer; and a material of the adhesion layer is selected from the group consisting of titanium, chromium, aluminum, and silver.

9. A fabrication method for the silicon-based infrared band avalanche photodetector according to claim 1, comprising:
placing pretreated silicon-on-insulator in a hydrofluoric acid solution, and removing an insulating layer to obtain the silicon film layer; and
fabricating the top metal film layer and the bottom electrode layer on an upper surface and a lower surface of the silicon film layer respectively by a physical and/or chemical method.

10. The fabrication method according to claim 9, wherein the pretreatment comprises a process of ultrasonic cleaning of the silicon-on-insulator with an organic solvent and water in sequence;
the insulating layer is a silicon dioxide layer; and
the physical and/or chemical method comprises magnetron sputtering deposition and electron beam evaporation.
